(19) United States
(12) Patent Application Publication
(10) Pub. No.: US 2024/0077801 A1
(43) Pub. Date: Mar. 7, 2024

(54) ZINC-BASED METAL ORGANIC NANOPARTICLE, PREPARATION METHOD THEREFOR, AND PHOTORESIST

(71) Applicants: TSINGHUA UNIVERSITY, Beijing (CN); BEIJING VFORTUNE NEW ENERGY POWER TECHNOLOGY DEVELOPMENT CO., LTD., Beijing (CN)

(72) Inventors: Hong XU, Beijing (CN); Xiangming HE, Beijing (CN); Hao CUI, Beijing (CN)

(21) Appl. No.: 18/259,262

(22) PCT Filed: Dec. 23, 2021
(86) PCT No.: PCT/CN2021/140846

§ 371 Date: Jun. 23, 2023

(30) Foreign Application Priority Data
Dec. 24, 2020 (CN) 202011547342.7
Dec. 21, 2021 (CN) 202111573387.6

(51) Int. Cl. G03F 7/00; G03F 7/004

(52) U.S. Cl. CPC G03F 7/002; G03F 7/0044

(57) ABSTRACT

Disclosed are a zinc-based metal organic nanoparticle and a preparation method therefor, and a photoresist. The zinc-based metal organic nanoparticle has a core-shell structure, and the general formula is ZnₓO_{y}[A]₂ₓ[B]₂, wherein x is 2 or 3, and 2x≤y≤4x, ZnₓO_{y} is a kernel of the core-shell structure, A is a first organic ligand, B is a second organic ligand, the first organic ligand A and the second organic ligand B together form an outer shell of the core-shell structure, the first organic ligand A is selected from one or more of a substituted or unsubstituted aliphatic group and a substituted or unsubstituted aromatic group, and the second organic ligand B is selected from one or more of an organic amine and a derivative thereof.

### CROSS-REFERENCE TO RELATED APPLICATIONS

This application claims priority to Chinese Patent Application No. 202011547342.7, filed on Dec. 24, 2020 and entitled “PHOTORESIST, PREPARATION METHOD, PATTERNING METHOD, AND METHOD FOR GENERATING PRINTED CIRCUIT BOARD”, and claims priority to Chinese Patent Application No. 202111573387.6, filed on Dec. 21, 2021 and entitled “ZINC-BASED METAL-ORGANIC NANOPARTICLE AND PREPARATION METHOD THEREOF, AND PHOTORESIST”, which are incorporated herein by reference in their entirety.

### TECHNICAL FIELD

This application relates to the field of photoresist technologies, and in particular, to a zinc-based metal-organic nanoparticle and a preparation method thereof, and a photoresist.

### BACKGROUND

Photoresists are corrosion-resistant materials whose solubility changes under the radiation of ultraviolet light, electron beams, particle beams, extreme ultraviolet (EUV) light, or X-rays. Photoresists are widely used for pattern transfer in processing of semiconductor integrated circuits and liquid crystal panels, and manufacturing of high-end optical devices. According to Moore's Law, the integration level of semiconductors per unit area doubles every 18 to 24 months. With the continuous advancement of semiconductor technologies, the size of semiconductors is continuously reduced, which has higher requirements on reduction of the feature size of semiconductors during processing. In order to satisfy a more advanced semiconductor process and obtain a smaller feature size, lithography is also constantly developing, from I-line, G-line, deep ultraviolet (DUV), 193 nm, and 193 nm immersion to lithography with fine processing such as extreme ultraviolet lithography and electron beam lithography.

A conventional photoresist has complex components, including a photoresist resin, a sensitizer, a leveling agent, a stabilizer, a dispersant, a thickener, a solvent, and the like. It has a cumbersome production process, and has extremely high requirements on processes of controlling proportions and purity. Since the conventional photoresist contains macromolecular polymers and various additives that make the composition complex, the size distribution of the components of the photoresist is wide, that is, there are components of various sizes. The size conformation of some components can reach 10 nm to 20 nm, so that the size of the photoresist pattern is difficult to control, and many defects may occur. In addition, the use of the conventional photoresist is limited by a wavelength of a light source. Different photoresists are required to match light sources at different wavelengths.

### SUMMARY

Based on the above, it is necessary to provide a zinc-based metal-organic nanoparticle and a preparation method thereof, and a photoresist.

A zinc-based metal-organic nanoparticle has a core-shell structure and has a general formula of ZnₓO_{y}[A]₂ₓ[B]₂, where x is 2 or 3, 2x≤y≤4x, ZnₓO_{y} is a core of the core-shell structure, A is a first organic ligand, B is a second organic ligand, the first organic ligand A and the second organic ligand B jointly form an exterior shell of the core-shell structure, the first organic ligand A is selected from one or more of a substituted or unsubstituted aliphatic group and a substituted or unsubstituted aromatic group, and the second organic ligand B is selected from one or more of an organic amine and a derivative thereof.

In some embodiments, the zinc-based metal-organic nanoparticle includes a photoreactive group.

In some embodiments, at least one of the first organic ligand A and the second organic ligand B includes the photoreactive group.

In some embodiments, the photoreactive group is selected from one or more of a carbon-carbon double bond, an acyloxy group, an acyl group, an aldehyde group, a carboxyl group, an ester group, and an amino group.

In some embodiments, x=3, and two Zn atoms are located at two opposite ends of the ZnₓO_{y} core and are respectively linked to two N atoms in the second organic ligand B.

In some embodiments, x=2, two Zn atoms are jointly linked to the first organic ligand A through surrounding O atoms, and two N atoms in the second organic ligand B are located at two ends of the ZnₓO_{y} core and are respectively linked to the two Zn atoms.

In some embodiments, the general formula of the zinc-based metal-organic nanoparticle is Zn₂O₈[A]₄[B]₂, Zn₃O₁₂[A]₆[B]₂, or Zn₃O₁₀[A]₆[B]₂.

In some embodiments, a size of the zinc-based metal-organic nanoparticle is 1 nm to 3 nm.

In some embodiments, the aliphatic group is a C1-C10 chain hydrocarbon group or a C3-C10 cyclic hydrocarbon group; and the aromatic group includes one or more aromatic rings, substituted aromatic rings, heteroaromatic rings, or substituted heteroaromatic rings, preferably phenyl or substituted phenyl.

In some embodiments, the first organic ligand A is represented by one or more of the following structure, where a dotted line represents a bond linked to O of the ZnₓO_{y} core:

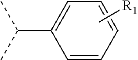

R₁ is independently selected from one or more of H, halogen, carboxyl, carbonyl, hydroxyl, amino, R, OR, NR₂, SR, C(O)R, C(O)OR, C(O)NR₂, CN, CF₃, NO₂, SO₂, SOR, and SO₃R. R is a substituent. In some embodiments, R is independently C1-C10 chain alkyl, C2-C10 chain alkenyl, C2-C10 chain alkynyl, C3-C10 aryl, C3-C10 alkylaryl, or C3-C10 cycloalkyl. In some embodiments, R is independently C1-C4 chain alkyl, C2-C4 chain alkenyl, C2-C4 chain alkynyl, phenyl, or alkylphenyl.

In some embodiments, the second organic ligand B is selected from any one or more of a chain amine and a derivative thereof, and a cyclic amine and a derivative thereof, the cyclic amine and the derivative thereof are selected from any one or more of imidazole and a derivative thereof, pyridine and a derivative thereof, pyrrole and a derivative thereof, pyrimidine and a derivative thereof, pyridazine and a derivative thereof, and piperidine and a derivative thereof, and the chain amine and the derivative thereof are selected from but are not limited to any one or more of trimethylamine, triethylamine, tripropylamine, triisopropylamine, triethanolamine, dimethylamine, diethylamine, dipropylamine, diisopropylamine, and ethyldiisopropylamine.

In some embodiments, the general formula of the zinc-based metal-organic nanoparticle is ZnₓO_{y}[A1,A2]₂ₓ[B1]₂, ZnₓO_{y}[A1]₂ₓ[B1,B2]₂, or ZnₓO_{y}[A1,A2]₂ₓ[B1,B2]₂, where A1 and A2 respectively represent two different first organic ligands A, and B1 and B2 respectively represent two different second organic ligands B.

A preparation method of the zinc-based metal-organic nanoparticle includes the following steps:
mixing a zinc metal salt and an organic solvent to obtain a zinc metal salt solution;
mixing the zinc metal salt solution with a first organic ligand source and a second organic ligand source, prior to heating and stirring for reaction; and
carrying out rotary evaporation under a vacuum on a product obtained through the reaction, to remove the organic solvent.

In some embodiments, a molar ratio of the zinc metal salt to the first organic ligand source to the second organic ligand source is 1:(0.5-6):(0.5-6).

A zinc-based metal-organic nanoparticle crystal is obtained through crystallization by redissolving the zinc-based metal-organic nanoparticle or a product obtained through the rotary evaporation under a vacuum in an organic solvent.

A photoresist is obtained by dispersing any one or both of the zinc-based metal-organic nanoparticle and the zinc-based metal-organic nanoparticle crystal in an organic dispersant.

In some embodiments, the photoresist is composed of the zinc-based metal-organic nanoparticle and the organic dispersant.

This application provides a new self-initiated zinc-based metal-organic nanoparticle based on a ZnₓO_{y} core and an organic ligand, which is also referred to as a photoresist particle. The photoresist particles can agglomerate under light without a photo-acid generator, a photo-acid catalyst, a photoinitiator, and the like, so that their solubility decreases in a developer, while the photoresist particles in an unexposed region cannot agglomerate but dissolve in the developer. Therefore, the unexposed region can be removed after development. In a case that only the photoresist particles are used, patterning can be carried out when exposed to ultraviolet light, deep ultraviolet light, electron beams, or extreme ultraviolet light, and extremely high photosensitivity and resolution can also be obtained.

### BRIEF DESCRIPTION OF THE DRAWINGS

To describe the technical solutions in embodiments of the present disclosure more clearly, the accompanying drawings to be used in the description of the embodiments will be briefly described below. Clearly, the accompanying drawings in the following description are only some embodiments of the present disclosure, and a person of ordinary skill in the art may further obtain other drawings based on these accompanying drawings without creative efforts.

FIG. 1 is a schematic diagram of a structure of a photoresist particle according to an embodiment of this application.

FIG. 2 is a graph of distribution of particle sizes of a photoresist particle according to an embodiment of this application and a conventional photoresist particle.

FIG. 3 is a diagram of a single crystal structure of a photoresist particle in Example 1 of this application.

FIG. 4 is a diagram of a chemical structure of a photoresist particle in Example 1 of this application.

FIG. 5 is a diagram of a single crystal structure of a photoresist particle in Example 2 of this application.

FIG. 6 is a diagram of a chemical structure of a photoresist particle in Example 2 of this application.

FIG. 7 is a diagram of a single crystal structure of a photoresist particle in Example 3 of this application.

FIG. 8 is a diagram of a chemical structure of a photoresist particle in Example 3 of this application.

FIG. 9 is a diagram of a single crystal structure of a photoresist particle in Example 4 of this application.

FIG. 10 is a diagram of a chemical structure of a photoresist particle in Example 4 of this application.

FIG. 11 is a scanning electron micrograph of a patterned photoresist layer obtained by exposing a photoresist particle in Example 5 of this application in a dose of 45 mJ/cm⁻² to deep ultraviolet light.

FIG. 12 is a scanning electron micrograph of a patterned photoresist layer obtained by exposing a photoresist particle in Example 5 of this application in a dose of 75 mJ/cm⁻² to deep ultraviolet light.

FIG. 13 is a scanning electron micrograph of a patterned photoresist layer obtained by exposing a photoresist particle in Example 5 of this application in a dose of 110 mJ/cm⁻² to deep ultraviolet light.

FIG. 14 is a scanning electron micrograph of a patterned photoresist layer obtained by exposing a photoresist particle in Example 5 of this application under a mask in a dose of 50 μC to electron beams.

FIG. 15 is a scanning electron micrograph of a patterned photoresist layer obtained by exposing a photoresist particle in Example 5 of this application under another mask in a dose of 50 μC to electron beams.

FIG. 16 is a scanning electron micrograph of a patterned photoresist layer obtained by exposing a photoresist particle in Example 5 of this application under still another mask in a dose of 50 μC to electron beams.

FIG. 17 is a scanning electron micrograph of a patterned photoresist layer obtained by exposing a photoresist particle in Example 5 of this application in a dose of 7 mJ/cm⁻² to extreme ultraviolet light.

FIG. 18 is an optical photograph of a patterned photoresist layer obtained by exposing a photoresist particle in Example 5 of this application in a dose of 300 mJ/cm⁻² under an air test condition to ultraviolet light at a wavelength of 254 nm.

FIG. 19 is a scanning electron micrograph of a patterned photoresist layer obtained by exposing a photoresist particle in Example 5 of this application in a dose of 300 mJ/cm⁻² under an air test condition to ultraviolet light at a wavelength of 254 nm.

### DETAILED DESCRIPTION

For easy understanding of this application, a more thorough description of this application will be given below with reference to the related drawings. Preferred embodiments of this application are given in the drawings. However, this application can be implemented in many different forms and is not limited to the embodiments described in this specification. On the contrary, the embodiments are provided for a more thorough understanding of the content disclosed in this application.

Unless otherwise defined, all technical and scientific terms used in this specification have the same meaning as would normally be understood by a person skilled in the art of this application. The terms used in this application are only for describing specific embodiments, but are not intended to limit this application.

The scope of the word “light” used in this application includes, but is not limited to, ultraviolet light, deep ultraviolet light, and extreme ultraviolet light, and also broadly covers electron beams, X-rays, and the like.

An embodiment of this application provides a photoresist particle. A crystal structure of the photoresist particle is a core-shell structure. A general formula of the photoresist particle is ZnₓO_{y}[A]₂ₓ[B]₂, where X is 2 or 3, 2x≤y≤4x, ZnₓO_{y} is a core of the core-shell structure, A is a first organic ligand, and B is a second organic ligand. The first organic ligand A and the second organic ligand B jointly form an exterior shell of the core-shell structure. The first organic ligand A is selected from one or more of a substituted or unsubstituted aliphatic group and a substituted or unsubstituted aromatic group. The second organic ligand B is selected from one or more of an organic amine and a derivative thereof. The photoresist particle may include a photoreactive group. Specifically, at least one of the first organic ligand A and the second organic ligand B may include the photoreactive group. Photoreactive groups of different photoresist particles may react with each other under light radiation, causing agglomeration of the photoresist particles, so that the solubility of an exposed region decreases in a developer.

A crystal state of the photoresist particles is a state obtained through crystallization after the photoresist particles dissolve in a solvent.

This application designs and prepares a new self-initiated metal oxide nanoparticle based on a ZnₓO_{y} core and an organic ligand (which is also referred to as a photoresist particle or a zinc-based metal-organic nanoparticle in this application). The photoresist particles agglomerate in a developer under light radiation, so that the solubility decreases. The photoresist particles in an unexposed region do not agglomerate but dissolve in the developer, so that the photoresist in the unexposed region can be removed after development. In particular, in a case that only the photoresist particles are used, patterning can be carried out when exposed to ultraviolet light, deep ultraviolet light, electron beams, or extreme ultraviolet light at different wavelengths, and extremely high photosensitivity and resolution can also be obtained. In the photoresist particle, a quantity of Zn atoms in the ZnₓO_{y} core is 2-3, and the exterior shell is formed by two organic ligands. The ZnₓO_{y} core has a high electron donating capability, and has high sensitivity to radiation of rays or particles at different wavelengths, causing agglomeration of the photoresist particles under radiation, so that the solubility of an exposed region decreases in a developer. With a synergistic effect of the ZnₓO_{y} core and the first organic ligand A and/or the second organic ligand B including the photoreactive group, the photoresist particles can be photosensitive to be directly used as a photoresist for patterning. The photoresist containing the photoresist particles can achieve a photosensitive effect without a photo-acid generator, a photo-acid catalyst, a photoinitiator, and the like.

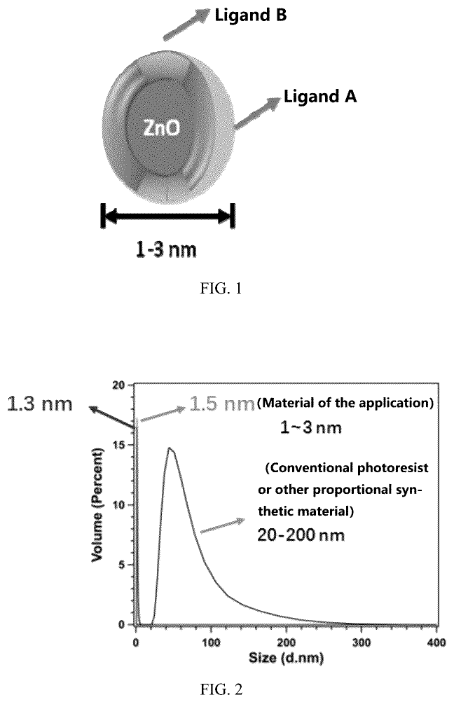

If the core of the photoresist particle is approximately regarded as a sphere with an equator and two poles, in some embodiments, a content of the first organic ligand A decreases from the equator to the poles on the core, and a content of the second organic ligand B decreases from the poles to the equator on the core. Optionally, the second organic ligand B is distributed from the poles to the equator in a range extending for 10° to 45°, and the first organic ligand A is distributed from the equator to the poles in a range extending for 45° to 80°. The angles herein refer to central angles on any section passing through a center of the sphere. Optionally, only the second organic ligand B is contained at the poles, and only the first organic ligand A is contained at the equator, as shown in FIG. 1.

Due to a small volume of the core, the core is basically wrapped in the organic ligands as a whole. The core is fully wrapped in the first organic ligand A and the second organic ligand B, and there is basically no gap on the exterior shell.

As shown in FIG. 2, a size of the photoresist particle is 1 nm to 3 nm. It can be learned from data representation of a single crystal structure that the first organic ligand A and the second organic ligand B cooperate with each other and form the photoresist particle that conforms to the general formula, and the photoresist particle has a precise structure. It can be learned from a material size that compared with a conventional photoresist, the photoresist in this application can significantly reduce edge roughness of an exposed pattern.

In the photoresist particle, each Zn atom in the ZnₓO_{y} core may be linked to the surrounding O atom and/or the N atom in the second organic ligand B. In some embodiments, a total quantity n of O and N atoms linked to the same Zn atom may be 4, 5, or 6, so as to form a tetrahedron (n=4), hexahedron (n=5), or octahedron (n=6) unit. The Zn atom is located at a center of the tetrahedron, hexahedron, or octahedron, and the O atom or N atom is located at a vertex of the tetrahedron, hexahedron, or octahedron. Adjacent Zn atoms may be directly linked through the O atom, to form a Zn—O—Zn bond. In this case, one oxygen atom can be shared between polyhedra. Alternatively, adjacent Zn atoms may be jointly linked to the same first organic ligand A through the O atom, to form a Zn—O—C—O—Zn group.

In some embodiments, x=3, and the three Zn atoms are arranged in sequence to form an acyclic structure. The two Zn atoms at both ends are directly linked to two N atoms in the second organic ligand B respectively, and the Zn atom at the center is only directly linked to the O atom. Since the N atoms come from the second organic ligand B, the second organic ligand B is located at the two poles of the core.

In some embodiments, x=2, the two Zn atoms are not directly linked through the O atom, but are jointly linked to the first organic ligand A through the surrounding O atoms, to form a Zn—O—C—O—Zn group. The two N atoms in the second organic ligand B are located at the two ends of the ZnₓO_{y} core and are linked to the two Zn atoms respectively. Since the N atoms come from the second organic ligand B, the second organic ligand B is located at the two poles of the core.

More specifically, in some embodiments, a general formula of the photoresist particle may be ZnₓO₄ₓ[A]₂ₓ[B]₂, such as Zn₂O₈[A]₄[B]₂ or Zn₃O₁₂[A]₆[B]₂. In some other embodiments, a general formula of the photoresist particle may be Zn₃O₁₀[A]₆[B]₂.

The first organic ligand A is directly linked to the O atom in the ZnₓO_{y} core through its C atom. The second organic ligand B is directly linked to the Zn atom in the ZnₓO_{y} core through its N atom. In some embodiments, the same first organic ligand A is linked to two O atoms, and is linked to two Zn atoms through the two O atoms. In the synthesis of the photoresist particle, at least some O atoms in the ZnₓO_{y} core are derived from a reactant for forming the first organic ligand A (also referred to as a first organic ligand source in this application), for example, from an oxygen-containing unsaturated bond in the first organic ligand A, such as a carboxyl or carbonyl group, so that the first organic ligand A is located between the two poles of the core, for example, at the equator.

The first organic ligand A is selected from a substituted or unsubstituted aliphatic group or a substituted or unsubstituted aromatic group. The aliphatic group may be a C1-C10 chain hydrocarbon group or a C3-C10 cyclic hydrocarbon group. The chain hydrocarbon group may be straight-chain or branched-chain alkyl, alkenyl, or alkynyl. In the substituted aliphatic group, hydrogen of the chain hydrocarbon group or the cyclic hydrocarbon group may be substituted by one or more substituents. The aromatic group may include one or more aromatic rings, substituted aromatic rings, heteroaromatic rings, or substituted heteroaromatic rings, and in some embodiments, may be phenyl or substituted phenyl. In the substituted aromatic group, hydrogen on the aromatic ring, for example, a benzene ring, may be substituted by one or more substituents. The substituent may be selected from but is not limited to one or more of halogen, carboxyl, carbonyl, hydroxyl, amino, R, OR, NR₂, SR, C(O)R, C(O)OR, C(O)NR₂, CN, CF₃, NO₂, SO₂, SOR, and SO₃R. R may be independently but is not limited to C1-C10 chain alkyl, C2-C10 chain alkenyl, C2-C10 chain alkynyl, C3-C10 aryl, C3-C10 alkylaryl, or C3-C10 cycloalkyl. In some embodiments, R is independently C1-C4 chain alkyl, C2-C4 chain alkenyl, C2-C4 chain alkynyl, phenyl, or alkylphenyl, specifically, for example, may be methyl, ethyl, n-propyl, isopropyl, n-butyl, isobutyl, vinyl, propenyl, ethynyl, or the like. The alkylphenyl may be, for example, methylphenyl, ethylphenyl, n-propylphenyl, or isopropylphenyl. In some embodiments, a total quantity of carbon atoms in each first organic ligand A may be 1-10. In some embodiments, the first organic ligand A is derived from any one or more of benzene and a derivative thereof, alkane, alkene, and carboxylic acid. The derivative may be obtained by substituting hydrogen atoms in benzene by the substituent.

In some embodiments, the first organic ligand A is represented by one or more of the following structure, where a dotted line represents a bond linked to O of the ZnₓO_{y} core:

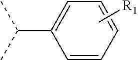

R₁ is independently selected from one or more of H, halogen, carboxyl, carbonyl, hydroxyl, amino, R, OR, NR₂, SR, C(O)R, C(O)OR, C(O)NR₂, CN, CF₃, NO₂, SO₂, SOR, and SO₃R. A quantity of R₁ is 1 to 5, and each R₁ is linked to C in a benzene ring. In some embodiments, R₁ is independently C1-C4 chain alkyl, C2-C4 chain alkenyl, or C2-C4 chain alkynyl.

In some embodiments, the first organic ligand A is selected from one or more of the following structures:

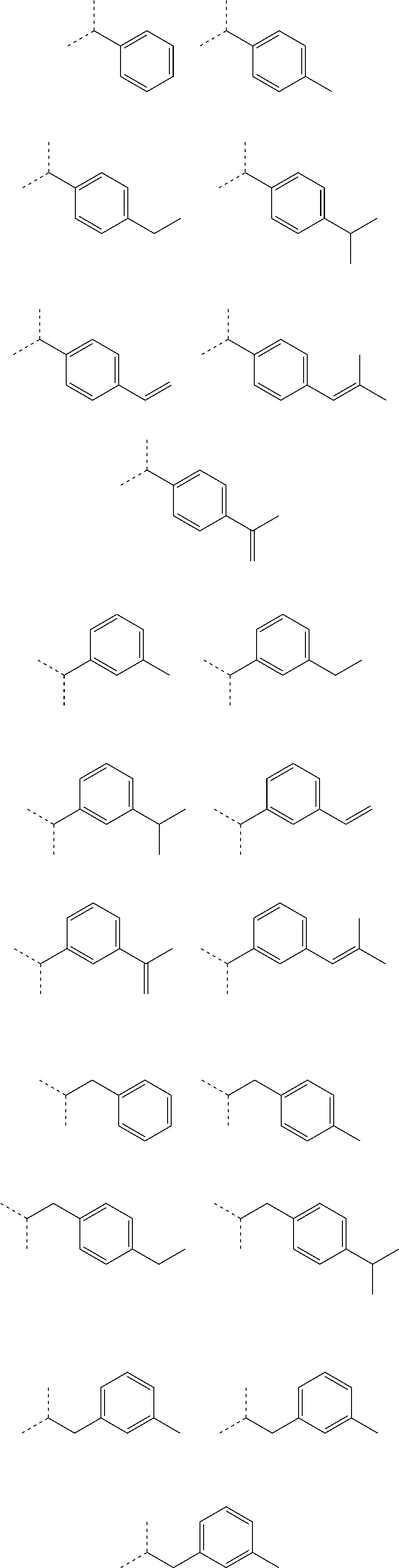

In some embodiments, the second organic ligand B is selected from an organic amine and a derivative thereof, including but not limited to any one or more of a chain amine and a derivative thereof, and a cyclic amine and a derivative thereof. The derivative may be a substituted chain amine or substituted cyclic amine formed by substituting hydrogen atoms in the organic amine by one or more substituents. The substituent may be selected from but is not limited to one or more of halogen, carboxyl, carbonyl, hydroxyl, amino, R, OR, NR₂, SR, C(O)R, C(O)OR, C(O)NR₂, CN, CF₃, NO₂, SO₂, SOR, and SO₃R. R may be independently but is not limited to H, C1-C10 chain alkyl, C2-C10 chain alkenyl, C2-C10 chain alkynyl, C3-C10 aryl, C3-C10 alkylaryl, or C3-C10 cycloalkyl. In some embodiments, R is independently C1-C4 chain alkyl, C2-C4 chain alkenyl, C2-C4 chain alkynyl, phenyl, or alkylphenyl, specifically, for example, may be methyl, ethyl, n-propyl, isopropyl, n-butyl, isobutyl, vinyl, propenyl, ethynyl, or the like. The alkylphenyl may be, for example, methylphenyl, ethylphenyl, n-propylphenyl, or isopropylphenyl.

In some embodiments, the cyclic amine and the derivative thereof may be selected from but are not limited to any one or more of imidazole and a derivative thereof, pyridine and a derivative thereof, pyrrole and a derivative thereof, pyrimidine and a derivative thereof, pyridazine and a derivative thereof, and piperidine and a derivative thereof. The chain amine and the derivative thereof may be selected from but are not limited to any one or more of trimethylamine, triethylamine, tripropylamine, triisopropylamine, triethanolamine, dimethylamine, diethylamine, dipropylamine, diisopropylamine, and ethyldiisopropylamine. The imidazole and the derivative thereof may be but are not limited to any one or more of methylimidazole and vinylimidazole. The pyridine and the derivative thereof may be but are not limited to any one or more of methylpyridine, vinylpyridine, methylpyridine alkane, and perhydropyridine. The pyrrole and the derivative thereof may be but are not limited to any one or more of methylpyrrole and vinylpyrrole. The pyridazine and the derivative thereof may be but are not limited to any one or more of vinylpyridazine and divinylpyridazine. The piperidine and the derivative thereof may be but are not limited to vinylpiperidine. In some embodiments, the second organic ligand B is an N-containing unsaturated structure, which can increase the electron donating capability, so that it is easier for the photoreactive group to obtain electrons, to have higher reactivity, thereby promoting reaction between the photoreactive groups.

In some embodiments, at least one of the first organic ligand A and the second organic ligand B may include the photoreactive group. Photoreactive groups of different photoresist particles may react with each other under light radiation, for example, generate a linking group, so that the photoresist particles are linked to each other through the linking group. The ZnₓO_{y} core has a high electron donating capability, making it easier for the photoreactive group to obtain electrons, to have higher reactivity, so that the photoresist particles can be photosensitive without a photo-acid generator, a photo-acid catalyst, a photoinitiator, and the like. The reaction between the photoreactive groups may be, for example, but is not limited to, one or more of an addition reaction and a condensation reaction. The addition reaction may be, for example, one or more of a radical addition reaction, a nucleophilic addition reaction, and an electrophilic addition reaction. The photoreactive group may be one or more of a carbon-carbon double bond, a carbonyl group (such as an acyloxy group, an acyl group, an aldehyde group, and an ester group), a carboxyl group, and an amino group.

In an embodiment, at least one of the first organic ligand A and the second organic ligand B includes the carbon-carbon double bond. Under light radiation, carbon-carbon double bonds of different photoresist particles may undergo a radical addition reaction to generate a linking group —C—C—.

In another embodiment, both the first organic ligand A and the second organic ligand B include the photoreactive group. The photoreactive group of the first organic ligand A is an aldehyde group (—CHO), and the photoreactive group of the second organic ligand B is an amino group (such as —NH— or —NH₂—). The foregoing two photoreactive groups of different photoresist particles may react with each other under light radiation to generate a linking group —C—N—.

In some embodiments, the first organic ligand A has an aromatic ring structure, and the second organic ligand B is selected from a cyclic amine and a derivative thereof, especially imidazole and a derivative thereof. The aromatic ring structure (for example, phenyl) of the first organic ligand A and the cyclic amine structure (for example, imidazolyl) of the second organic ligand B have high electron donating capabilities, so that it is easier for the photoreactive group to obtain electrons, thereby promoting reaction between the photoreactive groups.

In the photoresist particle, the first organic ligand A and the second organic ligand B may be respectively one or more organic ligands. For example, when the first organic ligand A and the second organic ligand B are respectively selected from one or two organic ligands, a general formula of the photoresist particle may be ZnₓO_{y}[A1,A2]₂ₓ[B1]₂, ZnₓO_{y}[A1]₂ₓ[B1,B2]₂, or ZnₓO_{y}[A1,A2]₂ₓ[B1,B2]₂. A1 and A2 respectively represent two different first organic ligands A, for example, two different substituted or unsubstituted aliphatic groups or aromatic groups. B1 and B2 respectively represent two different second organic ligands B, for example, two different organic amines.

An embodiment of this application further provides a preparation method of a photoresist particle, including the following steps:
mixing a zinc metal salt and an organic solvent to obtain a zinc metal salt solution;
mixing the zinc metal salt solution with a first organic ligand source and a second organic ligand source, prior to heating and stirring for reaction; and
carrying out rotary evaporation under a vacuum on a product obtained through the reaction, to remove the organic solvent.

A molar ratio of the zinc metal salt to the first organic ligand source to the second organic ligand source is 1:(0.5-6):(0.5-6).

The first organic ligand source is a reactant for forming the first organic ligand A, including a group as the first organic ligand A, that is, the substituted or unsubstituted aliphatic group or the substituted or unsubstituted aromatic group. The first organic ligand source further includes an oxygen-containing unsaturated bond that can react with the zinc metal salt, such as a carboxyl or carbonyl group. The second organic ligand participates in the reaction through its nitrogen atom to be linked to the Zn atom of the core, so that the second organic ligand can be directly used as the second organic ligand source.

In the preparation method of this application, the molar ratio of the zinc metal salt to the first organic ligand source to the second organic ligand source plays a key role in obtaining the photoresist particles with the foregoing specific structure of this application. The molar ratio of the zinc metal salt to the first organic ligand source to the second organic ligand source is 1:(0.5-6):(0.5-6). The solution obtained after the reaction and before removing the organic solvent is clear and transparent, and the generated photoresist particles are not precipitated as precipitates, but are uniformly dispersed in the organic solvent. If the first organic ligand source or the second organic ligand source is added too much or too little, only white precipitates that cannot be dissolved in the organic solvent are formed or the photoresist particles with the specific structure cannot be obtained.

In some embodiments, the heating and stirring are carried out at a temperature of 50° C. to 120° C. for 10 h to 40 h; optionally, the heating and stirring are carried out at a temperature of 50° C. to 80° C. for 15 h to 28 h. An excessively low temperature causes an excessively slow reaction. An excessively high temperature causes an unstable reaction to form white precipitates that cannot be dissolved in the organic solvent instead of the photoresist particles with the specific structure.

In some embodiments, the rotary evaporation is carried out under a vacuum at a temperature of 20° C. to 80° C., such as 20° C., 25° C., 30° C., 35° C., 40° C., 45° C., 50° C., 55° C., 60° C., 65° C., 70° C., 75° C., or 80° C. Optionally, the rotary evaporation is carried out under a vacuum at a temperature of 20° C. to 40° C. An excessively low temperature causes an excessively slow reaction. An excessively high temperature causes unstable properties of the photoresist particles under a vacuum, so that the groups are easily destroyed. The temperature of the rotary evaporation under a vacuum is usually lower than the temperature of the heating and stirring.

In some embodiments, the rotary evaporation is carried out under a vacuum under a pressure of 5 mbar to 40 mbar, such as 5 mbar, 10 mbar, 15 mbar, 20 mbar, 25 mbar, 30 mbar, 35 mbar, or 40 mbar.

The rotary evaporation under a vacuum is to rapidly remove the organic solvent, so that the crystal nucleus of the zinc-based metal-organic nanoparticle hardly grows, and a single crystal is formed, that is, the zinc-based metal-organic nanoparticles in a monodisperse state.

The organic solvent is not particularly limited, for example, may be selected from but is not limited to any one or more of ethyl acetate, butyl acetate, propylene glycol monoethyl ether acetate, propylene glycol methyl ether acetate, 1-ethoxy-2-propanol, methanol, ethanol, and propanol.

An embodiment of this application further provides a photoresist particle crystal. The photoresist particle crystal is obtained through crystallization by dissolving the photoresist particle of any one of the foregoing embodiments in an organic solvent. During the crystallization, the solvent may be slowly removed, so that the crystal nucleus of the zinc-based metal-organic nanoparticle grow. In an embodiment, the photoresist particles obtained through the rotary evaporation under a vacuum may be redissolved in an organic solvent, and then left to stand to fully volatilize the organic solvent, to obtain the photoresist particle crystal. In another embodiment, the product obtained through the reaction before the rotary evaporation under a vacuum may be directly left to stand to fully volatilize the organic solvent, to obtain the photoresist particle crystal. The photoresist particle crystal is observed by using a dual-microfocus single-crystal X-ray diffractometer, and analyzed by using the single-crystal analysis software Olex2, to obtain a single-crystal structure and size characteristics of the photoresist particle.

An embodiment of this application further provides a photoresist, obtained by dispersing any one or both of the photoresist particle and the photoresist particle crystal of any one of the foregoing embodiments in an organic dispersant. The dispersion in the organic dispersant is, for example, dissolving the photoresist particles in the organic solvent to form a clear and transparent solution.

In some embodiments, the organic dispersant may be selected from any one or more of ethyl acetate, butyl acetate, propylene glycol monoethyl ether acetate, propylene glycol methyl ether acetate, 1-ethoxy-2-propanol, methanol, ethanol, and propanol.

An embodiment of this application further provides a method for patterning a photoresist, including the following steps:
coating the photoresist on a surface of a substrate, and removing the organic dispersant from the photoresist, to form a pre-film-forming layer on the surface of the substrate;
radiating a light source through a mask on the pre-film-forming layer of the substrate to carry out an exposure operation, to form a photoresist particle agglomerate on an exposed region of the pre-film-forming layer; and
applying a developer to the exposed pre-film-forming layer, to dissolve an unexposed region covered by the mask on the pre-film-forming layer in the developer, so that the exposed region of the pre-film-forming layer remains on the substrate due to the formation of the photoresist particle agglomerate, to form a patterned photoresist layer.

The patterning of the photoresist in this application can be carried out without a photo-acid generator, a catalyst, and a photoinitiator.

An embodiment of this application further provides a photoresist combination product, including the photoresist of any one of the foregoing embodiments and a developer. The photoresist combination product is used for forming a patterned photoresist layer.

In some embodiments, a light source used for exposure is selected from any one of ultraviolet light, deep ultraviolet light, electron beams, and extreme ultraviolet light. A wavelength of the extreme ultraviolet light is 10 nm to 14 nm. A wavelength of the ultraviolet light may be, for example, 254 nm or 365 nm. The photoresist in this application can be used under any light source for exposure in existing lithography technologies, without a photo-acid generator, a catalyst, and an initiator.

In some embodiments, the substrate is selected from a silicon substrate, or another substrate that is insoluble in the developer and selected according to actual needs.

In some embodiments, with regard to the mask, when the exposure is carried out under a deep ultraviolet light source or a light source at a longer wavelength, the mask used is a transmission mask; when the exposure is carried out under an extreme ultraviolet light source, the mask used is a reflection mask; and when a light source for exposure is an electron beam source, the mask may or may not be set, and the pre-film-forming layer is exposed under electron beams according to a pattern set by the software.

In some embodiments, the exposure operation is carried out under an ultraviolet, deep ultraviolet, or extreme ultraviolet light source in an exposure dose of 4 mJ/cm² to 1000 mJ/cm². In some other embodiments, the exposure operation is carried out under an electron beam source in a dose of 10 μC/cm² to 10 mC/cm². The exposure dose should be controlled within an appropriate range. If the exposure dose is excessively low, the energy is excessively low, which is not conducive to the agglomeration of the photoresist particles in the exposed region, and is not conducive to making a difference in solubility between the exposed region and the unexposed region, leading to a poor development effect. If the exposure dose is excessively high, the photoresist in the unexposed region may undergo a reaction, leading to a decrease in pattern precision.

In some embodiments, the developer is primarily used to dissolve the photoresist particles that do not agglomerate. An agglomerate formed from the photoresist particles in the exposed region is insoluble in the developer. Alternatively, an agglomerate in the exposed region has low solubility in the developer, so even if the agglomerate partially dissolves, the exposed region can still be covered by the agglomerate. The developer and the organic solvent in the photoresist may be the same or different. Optionally, the solubility of the photoresist particles in the developer is lower than the solubility of the photoresist particles in the organic solvent of the photoresist, to avoid a decrease in exposed pattern precision due to full or partial dissolution of the exposed region because the photoresist particles are dissolved in the developer due to insufficient agglomeration after exposure. In some embodiments, the developer may be selected from any one or more of decalin, tetralin, indene, indane, quinoline, 1-methylnaphthalene, toluene, ortho-xylene, meta-xylene, para-xylene, ethyl acetate, butyl acetate, ethanol, n-propanol, isopropanol, n-butanol, n-hexane, and cyclohexane. In some embodiments, the development may be carried out at room temperature, for example, 20° C. to 30° C.

In an embodiment, a thickness of the pre-film-forming layer obtained after the organic dispersant is removed may be 10 nm to 500 nm. Specifically, the thickness of the pre-film-forming layer may be 10 nm to 50 nm, 50 nm to 100 nm, 100 nm to 150 nm, 150 nm to 200 nm, 200 nm to 250 nm, 250 nm to 300 nm, 300 nm to 350 nm, 350 nm to 400 nm, 400 nm to 450 nm, or 450 nm to 500 nm.

An embodiment of this application further provides a method for generating a printed circuit board, including the following steps:
preparing a pre-patterned board with a patterned photoresist layer on a silicon substrate according to the method for patterning a photoresist; and
dry or wet etching the pre-patterned board.

### EXAMPLE 1

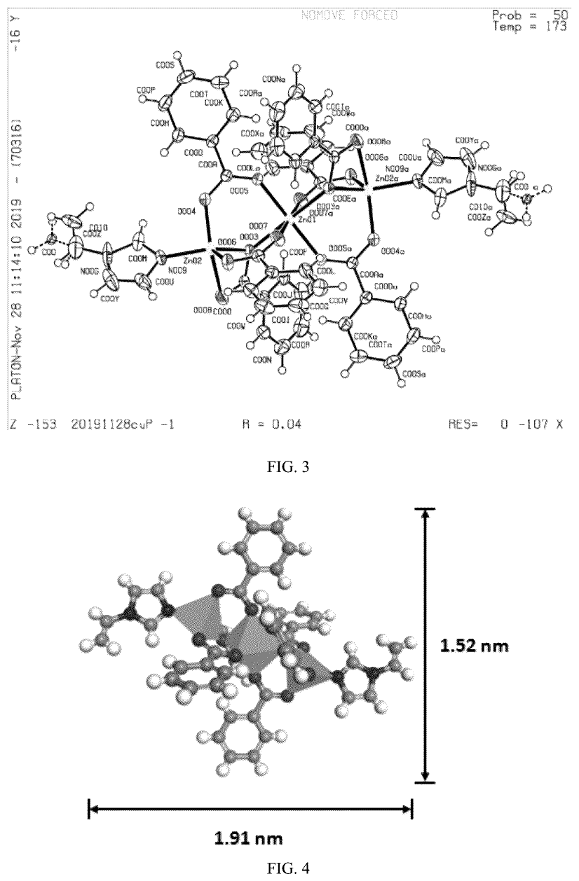

1. 4.88 g (20 mmol) of benzoic acid and 1.92 g (20.4 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min, to obtain a photoresist particle agglomerate. The agglomerate was redissolved in ethyl acetate, and then left to stand to fully volatilize ethyl acetate, to obtain a crystal. The photoresist particle crystal was observed by using a dual-microfocus single-crystal X-ray diffractometer, and analyzed by using the single-crystal analysis software Olex2, to obtain a diagram of a single crystal structure shown in FIG. 3. The obtained photoresist particle has the chemical formula of Zn₃O₁₂[C₇H₅]₆[C₅N₂H₆]₂ with a particle size less than 2 nm, as shown in FIG. 4.

### EXAMPLE 2

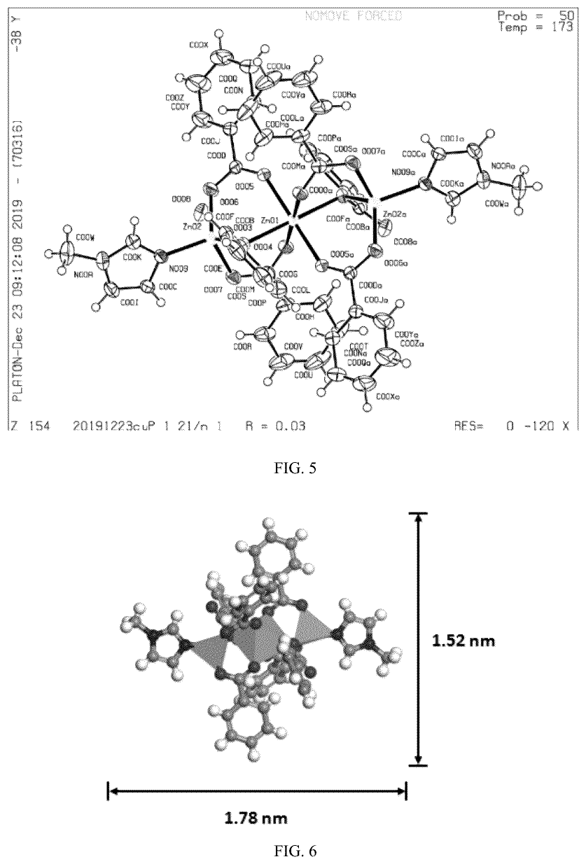

1. 4.88 g (20 mmol) of benzoic acid and 1.67 g (20.4 mmol) of N-methylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min, to obtain a photoresist particle agglomerate. The agglomerate was redissolved in ethyl acetate, and then left to stand to fully volatilize ethyl acetate, to obtain a crystal. The photoresist particle crystal was observed by using a dual-microfocus single-crystal X-ray diffractometer, and analyzed by using the single-crystal analysis software Olex2, to obtain a diagram of a single crystal structure shown in FIG. 5. The obtained photoresist particle has the chemical formula of Zn₃O₁₂[C₇H₅]₆[C₄N₂H₆]₂ with a particle size less than 2 nm, as shown in FIG. 6.

### EXAMPLE 3

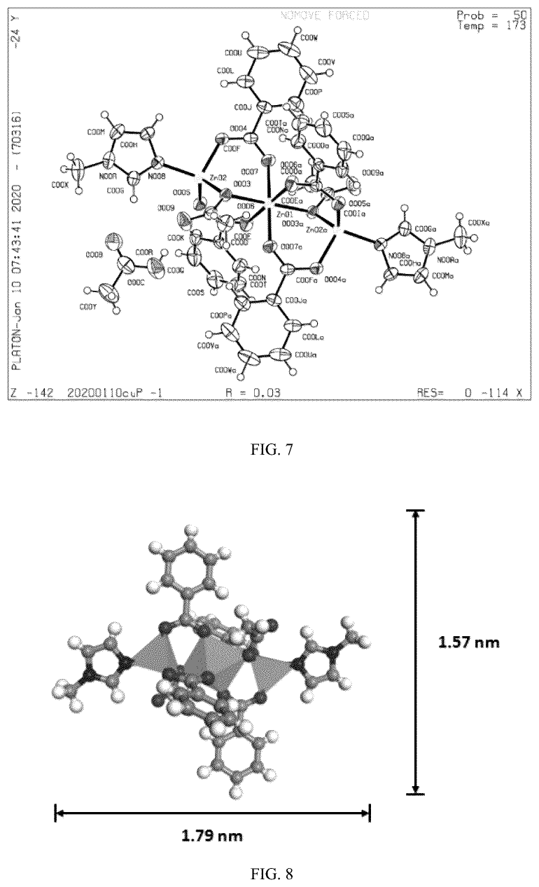

1. 2.44 g (10 mmol) of benzoic acid and 1.67 g (20.4 mmol) of N-methylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min, to obtain a photoresist particle agglomerate. The agglomerate was redissolved in ethyl acetate, and then left to stand to fully volatilize ethyl acetate, to obtain a crystal. The photoresist particle crystal was observed by using a dual-microfocus single-crystal X-ray diffractometer, and analyzed by using the single-crystal analysis software Olex2, to obtain a diagram of a single crystal structure shown in FIG. 7. The obtained photoresist particle has the chemical formula of Zn₃O₁₀[C₇H₅]₄[C₂H₃O]₂[C₄N₂H₆]₂ with a particle size less than 2 nm, as shown in FIG. 8.

### EXAMPLE 4

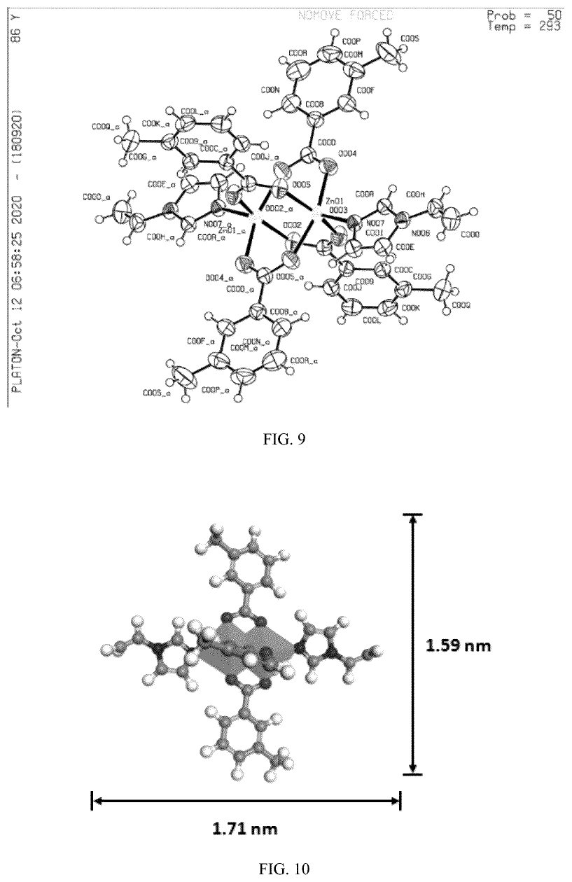

1. 5.44 g (20 mmol) of m-toluic acid and 1.92 g (20.4 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 2 h for reaction.
3. The resultant solution obtained after the reaction was subjected to rotary evaporation by using a rotary evaporator at 30° C. under a pressure controlled to be 30 mbar for 20 min, to obtain a photoresist particle agglomerate. The agglomerate was redissolved in ethyl acetate, and then left to stand to fully volatilize ethyl acetate, to obtain a crystal. The photoresist particle crystal was observed by using a dual-microfocus single-crystal X-ray diffractometer, and analyzed by using the single-crystal analysis software Olex2, to obtain a diagram of a single crystal structure shown in FIG. 9. The obtained photoresist particle has the chemical formula of Zn₂O₈[C₈H₇]₄[C₄N₂H₆]₂ with a particle size less than 2 nm, as shown in FIG. 10.

### EXAMPLE 5

1. 2.72 g (20 mmol) of m-toluic acid, 2.44 g (20 mmol) of benzoic acid, and 1.92 g (20.4 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min, to obtain a photoresist particle agglomerate. The agglomerate was redissolved in ethyl acetate, and then left to stand to fully volatilize ethyl acetate, to obtain a crystal. The photoresist particle crystal was observed by using a dual-microfocus single-crystal X-ray diffractometer, and analyzed by using the single-crystal analysis software Olex2. It was found that a mixture of two types of photoresist particles was obtained. The diagrams of the single crystal structures of the two types of the photoresist particles are shown in FIG. 3 and FIG. 9 respectively.

### Preparation of Patterned Photoresist Layer

1 g of the photoresist particles obtained in Example 5 were dissolved in 19 g of propylene glycol methyl ether acetate to disperse uniformly, to obtain a mixture for coating.

The mixture was coated on a 2-inch silicon wafer at a rotational speed of 2000 rpm for 1 min, and then baked at 80° C. for 1 min, to form a photoresist layer, that is, the pre-film-forming layer on the silicon wafer.

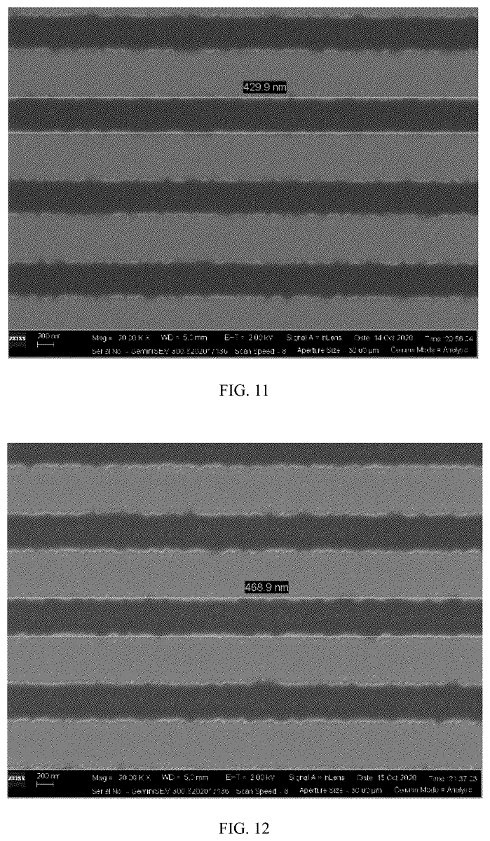

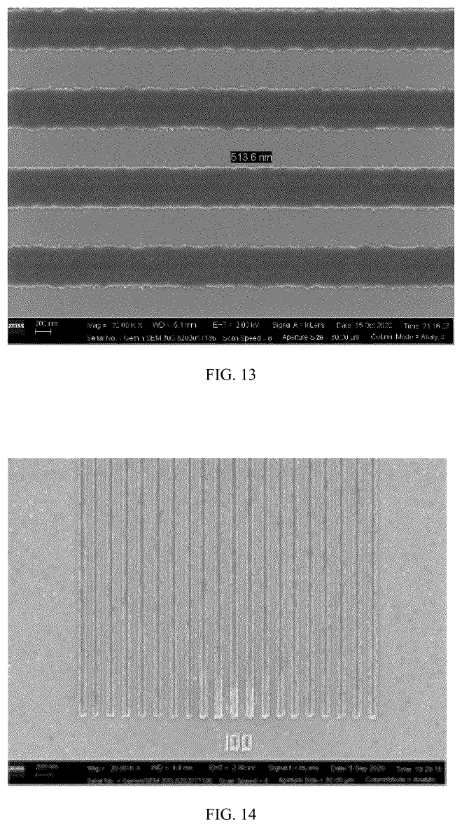

A plurality of same pre-film-forming layer samples were exposed through a patterned mask to the radiation of a 248 nm deep ultraviolet light source in different exposure doses, and then the exposed pre-film-forming layers were developed with a developer. The developer used was decalin. The exposure doses were respectively 45 mJ/cm⁻², 75 mJ/cm⁻², and 110 mJ/cm⁻². The obtained patterned photoresist layers are shown in FIG. 11 to FIG. 13. The line widths of the line patterns are respectively 429.9 nm, 468.9 nm, and 513.6 nm. It can be learned that, with the increase of the exposure dose, the line width of the line pattern formed through the same mask increases to a certain extent, but by about 0.4 μm to 0.5 μm.

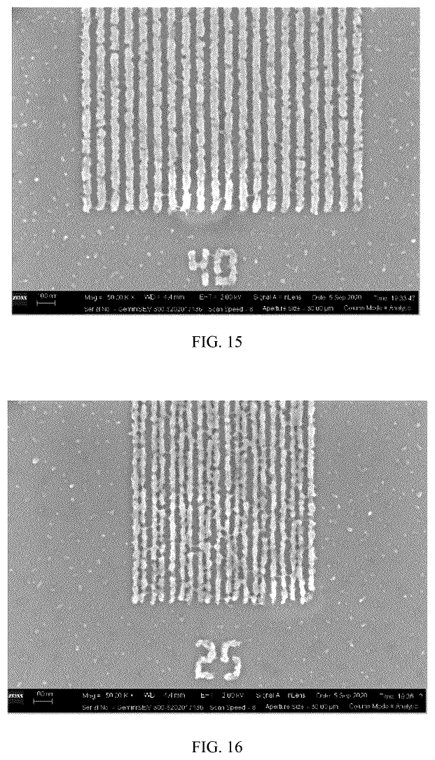

A plurality of same pre-film-forming layer samples were exposed through different patterned masks to the radiation of the same electron beam source in an exposure dose of 50 μC, and then the exposed pre-film-forming layers were developed with a developer of decalin. The obtained patterned photoresist layers are shown in FIG. 14 to FIG. 16. The line patterns are dense lines with line widths of 100 nm, 40 nm, and 25 nm respectively. A width ratio of each line to each space (L/S) is 1:1.

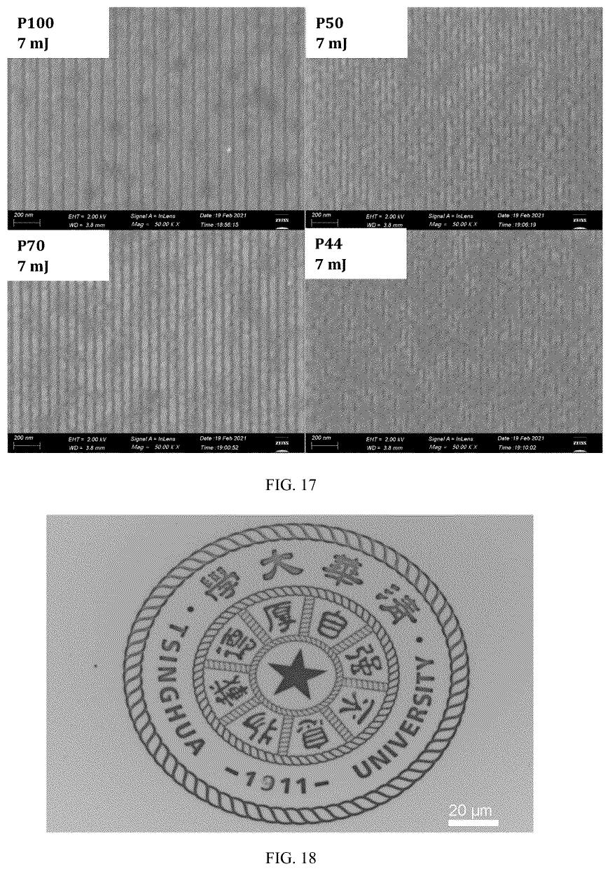

A plurality of same pre-film-forming layer samples were exposed through different patterned masks to the radiation of the same extreme ultraviolet light source in an exposure dose of 7 mJ/cm⁻², and then the exposed pre-film-forming layers were developed with a developer of decalin. The obtained patterned photoresist layers are shown in FIG. 17. Periods (that is, a sum of widths of a line and a space) of the patterns are respectively 100 nm (P100), 70 nm (P70), 50 nm (P50), and 44 nm (P44).

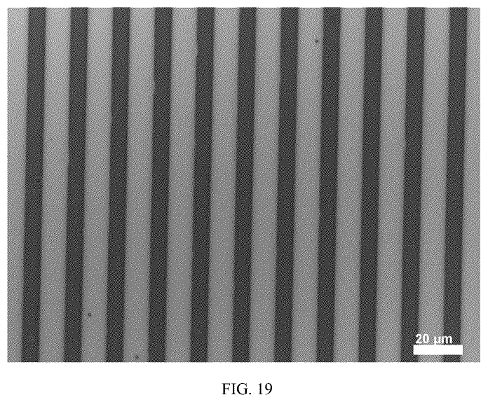

Pre-film-forming layer samples were exposed through different patterned masks to the radiation of a 254 nm ultraviolet light source in an exposure dose of 300 mJ/cm⁻², and then the exposed pre-film-forming layers were developed with a developer of tetralin. The obtained patterned photoresist layers are shown in FIG. 18 and FIG. 19. In FIG. 19, the line width of the line pattern is 8.87 μm. The exposure was carried out under an air test condition. Oxygen inhibits the reaction, so a high exposure dose is required.

It can be learned that a photolithographic pattern can be formed when exposed to ultraviolet light, deep ultraviolet light, extreme ultraviolet light, or electron beams without an initiator and a catalyst.

### Comparative Example 1

1. 1.22 g (5 mmol) of benzoic acid and 1.92 g (20.4 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min.

Because the content of benzoic acid in Comparative Example 1 was excessively low, white precipitates were produced in the resultant solution obtained after the reaction in the step 2, so that the photoresist particles cannot be obtained.

### Comparative Example 2

1. 48.8 g (200 mmol) of benzoic acid and 1.92 g (20.4 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min.

Because the content of benzoic acid in Comparative Example 2 was excessively high, white precipitates were produced in the resultant solution obtained after the reaction in the step 2, so that the photoresist particles cannot be obtained.

### Comparative Example 3

1. 4.88 g (20 mmol) of benzoic acid and 0.48 g (5.1 mmol) of N-vinylimidazole were added and mixed in a flask, and 15 mL of ethyl acetate was added to mix and dissolve for 2 min, to obtain a mixed solution.
2. 4.38 g (20 mmol) of zinc acetate dihydrate and 30 mL of ethyl acetate were added in another flask, and the mixed solution obtained in the step 1 was added in the flask dropwise, prior to stirring at 65° C. for 24 h for reaction.
3. The resultant solution obtained after the reaction was subjected to rotary evaporation by using a rotary evaporator at 30° C. under a pressure controlled to be 30 mbar for 20 min.

Because the content of N-vinylimidazole in Comparative Example 3 was excessively low, white precipitates were produced in the resultant solution obtained after the reaction in the step 2, so that the photoresist particles cannot be obtained.

The technical features of the foregoing embodiments can be randomly combined. To make the description concise, all possible combinations of the technical features of the foregoing embodiments have not been described. However, as long as there is no contradiction in the combinations of these technical features, they should be considered as the scope described in this specification.

The foregoing embodiments are merely illustrations of several implementations of this application and the description thereof is more specific and detailed, but cannot therefore be construed as limiting the scope of this application. It should be noted that several modifications and improvements may be made by those of ordinary skill in the art without departing from the concept of this application, all of which fall within the protection scope of this application. Therefore, the protection scope of this application shall be subject to the appended claims.

1. A zinc-based metal-organic nanoparticle, wherein the zinc-based metal-organic nanoparticle is a core-shell structure, and a general formula of the zinc-based metal-organic nanoparticle is ZnₓO_{y}[A]₂ₓ[B]₂, wherein x is 2 or 3, 2x≤y≤4x, ZnₓO_{y} is a core of the core-shell structure, A is a first organic ligand, B is a second organic ligand, the first organic ligand A and the second organic ligand B jointly form an exterior shell of the core-shell structure, the first organic ligand A is selected from one or more of a substituted or unsubstituted aliphatic group and a substituted or unsubstituted aromatic group, and the second organic ligand B is selected from one or more of an organic amine and a derivative thereof.

2. The zinc-based metal-organic nanoparticle according to claim 1, wherein the zinc-based metal-organic nanoparticle comprises a photoreactive group including at least one of the first organic ligand A and the second organic ligand B.

3. The zinc-based metal-organic nanoparticle according to claim 2, wherein the photoreactive group is selected from one or more of a carbon-carbon double bond, an acyloxy group, an acyl group, an aldehyde group, an ester group, a carboxyl group, and an amino group.

4. The zinc-based metal-organic nanoparticle according to claim 1, wherein x=3, and two Zn atoms are located at two opposite ends of the ZnₓO_{y} core and are respectively linked to two N atoms in the second organic ligand B.

5. The zinc-based metal-organic nanoparticle according to claim 1, wherein x=2, two Zn atoms are jointly linked to the first organic ligand A through surrounding O atoms, and two N atoms in the second organic ligand B are located at two ends of the ZnₓO_{y} core and are respectively linked to the two Zn atoms.

6. The zinc-based metal-organic nanoparticle according to claim 1, wherein the general formula of the zinc-based metal-organic nanoparticle is Zn₂O₈[A]₄[B]₂, Zn₃O₁₂[A]₆[B]₂, or Zn₃O₁₀[A]₆[B]₂.

7. The zinc-based metal-organic nanoparticle according to claim 1, wherein a size of the zinc-based metal-organic nanoparticle is 1 nm to 3 nm.

8. The zinc-based metal-organic nanoparticle according to claim 1, wherein the aliphatic group is a C1-C10 chain hydrocarbon group or a C3-C10 cyclic hydrocarbon group that includes a straight-chain or branched-chain alkyl, alkenyl, or alkynyl; and
the aromatic group comprises one or more aromatic rings, substituted aromatic rings, heteroaromatic rings, or substituted heteroaromatic rings including phenyl or substituted phenyl.

9. The zinc-based metal-organic nanoparticle according to claim 8, wherein in the substituted aliphatic group, hydrogen of the chain hydrocarbon group or the cyclic hydrocarbon group is substituted by one or more substituents; and in the substituted aromatic group, hydrogen on the aromatic ring is substituted by one or more substituents;
the substituent is selected from one or more of halogen, carboxyl, carbonyl, hydroxyl, amino, R, OR, NR₂, SR, C(O)R, C(O)OR, C(O)NR₂, CN, CF₃, NO₂, SO₂, SOR, and SO₃R, wherein R is independently C1-C10 chain alkyl, C2-C10 chain alkenyl, C2-C10 chain alkynyl, C3-C10 aryl, C3-C10 alkylaryl, or C3-C10 cycloalkyl.

10. The zinc-based metal-organic nanoparticle according to claim 1, wherein the first organic ligand A is represented by one or more of the following structure, wherein a dotted line represents a bond linked to O of the ZnₓO_{y} core: 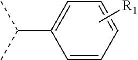
R₁ is independently selected from one or more of H, halogen, carboxyl, carbonyl, hydroxyl, amino, R, OR, NR₂, SR, C(O)R, C(O)OR, C(O)NR₂, CN, CF₃, NO₂, SO₂, SOR, and SO₃R, wherein R is independently C1-C10 chain alkyl, C2-C10 chain alkenyl, C2-C10 chain alkynyl, C3-C10 aryl, C3 -C10 alkylaryl, or C3 -C 10 cycloalkyl;
a quantity of R₁ is 1 to 5, and each R₁ is linked to C in a benzene ring;
R₁ is independently C1-C4 chain alkyl, C2-C4 chain alkenyl, or C2-C4 chain alkynyl; and
the first organic ligand A is selected from one or more of the following structures:

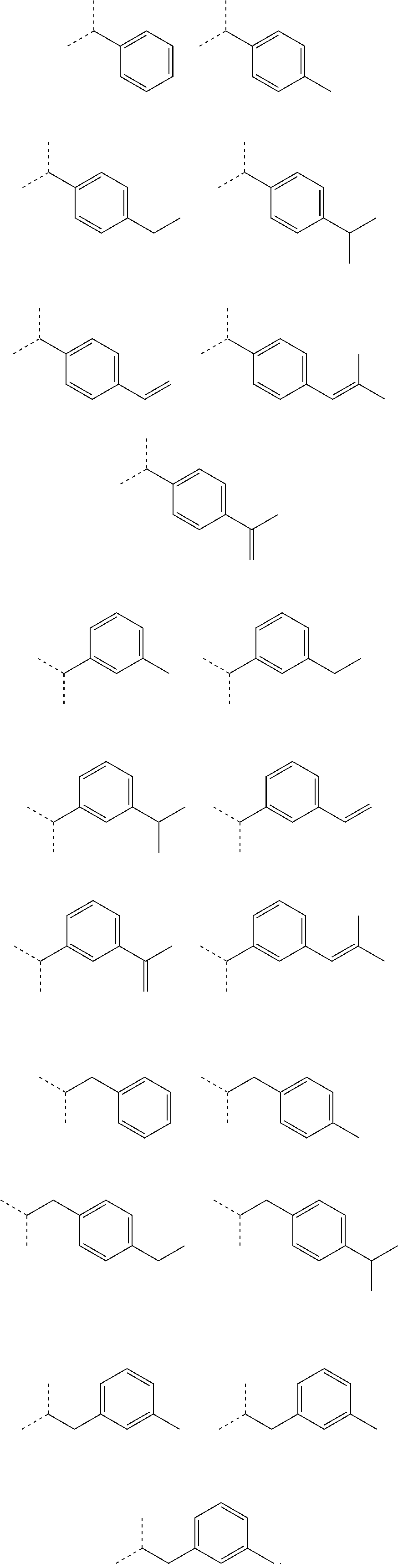

11. The zinc-based metal-organic nanoparticle according to claim 1, wherein the second organic ligand B is selected from any one or more of a chain amine and a derivative thereof, and a cyclic amine and a derivative thereof, the cyclic amine and the derivative thereof are selected from any one or more of imidazole and a derivative thereof, pyridine and a derivative thereof, pyrrole and a derivative thereof, pyrimidine and a derivative thereof, pyridazine and a derivative thereof, and piperidine and a derivative thereof, and the chain amine and the derivative thereof are selected from but are not limited to any one or more of trimethylamine, triethylamine, tripropylamine, triisopropylamine, triethanolamine, dimethylamine, diethylamine, dipropylamine, diisopropylamine, and ethyldiisopropylamine;
the imidazole and the derivative thereof are selected from any one or more of methylimidazole and vinylimidazole, the pyridine and the derivative thereof are selected from any one or more of methylpyridine, vinylpyridine, methylpyridine alkane, and perhydropyridine, the pyrrole and the derivative thereof are selected from any one or more of methylpyrrole and vinylpyrrole, the pyridazine and the derivative thereof are selected from any one or more of vinylpyridazine and divinylpyridazine, and the piperidine and the derivative thereof are vinylpiperidine.

12. The zinc-based metal-organic nanoparticle according to claim 11, wherein the derivative of the organic amine is obtained by substituting hydrogen atoms on the chain amine and/or the cyclic amine by one or more substituents;
the substituent is selected from one or more of halogen, carboxyl, carbonyl, hydroxyl, amino, R, OR, NR₂, SR, C(O)R, C(O)OR, C(O)NR₂, CN, CF₃, NO₂, SO₂, SOR, and SO₃R, wherein R is independently H, C1-C10 chain alkyl, C2-C10 chain alkenyl, C2-C10 chain alkynyl, C3-C10 aryl, C3-C10 alkylaryl, or C3-C10 cycloalkyl.

13. The zinc-based metal-organic nanoparticle according to claim 1, wherein the general formula of the zinc-based metal-organic nanoparticle is ZnₓO_{y}[A1,A2]₂ₓ[B1]₂, ZnₓO_{y}[A1]₂ₓ[B1,B2]₂, or ZnₓO_{y}[A1,A2]₂ₓ[B1,B2]₂, wherein A1 and A2 respectively represent two different first organic ligands A, and B1 and B2 respectively represent two different second organic ligands B.

14. A preparation method of the zinc-based metal-organic nanoparticle according to claim 1, comprising the following steps:
mixing a zinc metal salt and an organic solvent to obtain a zinc metal salt solution;
mixing the zinc metal salt solution with a first organic ligand source and a second organic ligand source, prior to heating and stirring for reaction; and
carrying out rotary evaporation under a vacuum on a product obtained through the reaction, to remove the organic solvent.

15. The preparation method of the zinc-based metal-organic nanoparticle according to claim 14, wherein a molar ratio of the zinc metal salt to the first organic ligand source to the second organic ligand source is 1:(0.5-6):(0.5-6).

16. The preparation method of the zinc-based metal-organic nanoparticle according to claim 15, wherein the heating and stirring are carried out at a temperature of 50° C. to 120° C. for 10 h to 40 h;
the rotary evaporation is carried out under a vacuum at a temperature of 20° C. to 80° C.; and
the rotary evaporation is carried out under a vacuum under a pressure of 5 mbar to 40 mbar.

17. A zinc-based metal-organic nanoparticle crystal, obtained through crystallization by redissolving the zinc-based metal-organic nanoparticle according to claim 1.

18. A photoresist, obtained by dispersing any one or both of the zinc-based metal-organic nanoparticles according claim 1 and a zinc-based metal-organic nanoparticle crystal obtained through crystallization by redissolving the zinc-based metal-organic nanoparticle.

19. The photoresist according to claim 18, wherein the organic dispersant is selected from any one or more of ethyl acetate, butyl acetate, propylene glycol monoethyl ether acetate, propylene glycol methyl ether acetate, 1-ethoxy-2-propanol, methanol, ethanol, and propanol.

20. A product obtained through the rotary evaporation under a vacuum in the preparation method of the zinc-based metal-organic nanoparticle according to claim 14.
